(19) United States
(12) Patent Application Publication
(10) Pub. No.: US 2016/0064191 A1
(43) Pub. Date: Mar. 3, 2016

(54) ION CONTROL FOR A PLASMA SOURCE

(71) Applicant: Sputtering Components, Inc., Owatonna, MN (US)

(72) Inventor: Patrick Lawrence Morse, Tucson, AZ (US)

(21) Appl. No.: 14/939,759

(22) Filed: Nov. 12, 2015

Related U.S. Application Data
(63) Continuation-in-part of application No. 13/932,632, filed on Jul. 1, 2013, now Pat. No. 9,198,274.
(60) Provisional application No. 61/668,075, filed on Jul. 5, 2012.

(51) Int. Cl. H01J 37/32; C23C 14/35; C23C 14/34; H01J 37/34

(52) U.S. Cl. CPC H01J 37/32055; H01J 37/3405; C23C 14/35; C23C 14/3492; H01J 2237/3321; H01J 2237/327

(57) ABSTRACT

One embodiment is directed to an apparatus including a plasma source and operation electronics coupled to the plasma source. The plasma source includes at least two electrodes configured to generate plasma. The operation electronics are configured to generate plasma with the at least two electrodes and apply an ion flux modification bias to the at least two electrodes.

### CROSS-REFERENCE TO RELATED APPLICATIONS

This application is a continuation-in-part of U.S. application Ser. No. 13/932,632, filed on Jul. 1, 2013, which claims the benefit of U.S. Provisional Patent Application Ser. No. 61/668,075, filed on Jul. 5, 2012, both of which are hereby incorporated herein by reference.

### BACKGROUND

Plasma-enhanced chemical vapor deposition (PECVD) is a process used to deposit thin films on a substrate. PECVD systems are well suited for the deposition of metal oxides as a majority of the precursors used readily react with oxygen.

Some PECVD processes use a magnetically confined plasma source having two or more electrodes that are alternatingly biased as cathodes and anodes to generate plasma that can be used to activate a precursor material on or near the substrate. An example of such a plasma source is a plasma source that generates a plasma within a cavity such that the plasma discharges out of the cavity toward a substrate.

German Patent DE19928053 describes an example of such a plasma source. DE19928053 describes a 50 kHz plasma source that uses of a pair of electrodes that are configured to operate as a cold cathode with the electrodes being biased as alternating cathodes and anodes. Such a plasma source can make use of an alternating current (AC) or bipolar pulse DC power supplies. However, in some applications (especially applications where a high energy ion beam is needed) the electrode switching provided in such a plasma source might not create an ion flux with sufficient energy levels on the substrate surface for the application.

A sputter magnetron is another example of a magnetically confined plasma source having two or more electrodes that can be alternatively biased as cathode and anode to generate plasma. Example sputter magnetrons include planar sputter magnetrons, in which the electrodes are stationary and planar in geometry, and rotary sputter magnetrons, in which the electrodes are cylindrical in geometry and rotate about the axis of the cylinder.

### SUMMARY

One embodiment is directed to an apparatus including a plasma source and operation electronics coupled to the plasma source. The plasma source includes at least two electrodes configured to generate plasma. The operation electronics are configured to generate plasma with the at least two electrodes and apply an ion flux modification bias to the at least two electrodes.

Another embodiment is directed to a method of controlling a plasma source having at least two electrodes that are configured to generate plasma. The method includes generating plasma with the at least two electrodes and applying an ion flux modification bias to the at least two electrodes.

Yet another embodiment is directed to an electrical circuit for a plasma source. The electrical circuit includes a switching unit and a controller. The switching unit is configured to couple to at least two electrodes of the plasma source, wherein the at least two electrodes configured to generate plasma. The controller is coupled to the switching unit. The controller is configured to control the switching unit to generate plasma with the at least two electrodes and to apply an ion flux modification bias to the at least two electrodes.

### DRAWINGS

FIG. 1A is a block diagram of an exemplary embodiment of a plasma source in which the ion control techniques described here can be employed.

FIG. 1B is a cross section of the exemplary plasma source of FIG. 1A taken along line 1B-1B.

FIG. 2 is a block diagram of an exemplary embodiment of another plasma source, in the form of a sputter magnetron, in which the ion control techniques described here can be employed.

FIG. 3 is a flow diagram of an exemplary embodiment of a method for ion control in a sputtering component having two or more electrodes such as the plasma source of FIG. 1 or the sputter magnetron of FIG. 2.

FIG. 4 is a flow diagram of an implementation of the method of FIG. 3.

FIG. 5 illustrates the operation of the exemplary method shown in FIG. 4 using a positive ion flux modification bias.

FIG. 6 illustrates the operation of the exemplary method shown in FIG. 4 using a negative ion flux modification bias.

FIG. 7 is a block diagram of an example power supply for use in the systems of FIGS. 1 and 2.

### DETAILED DESCRIPTION

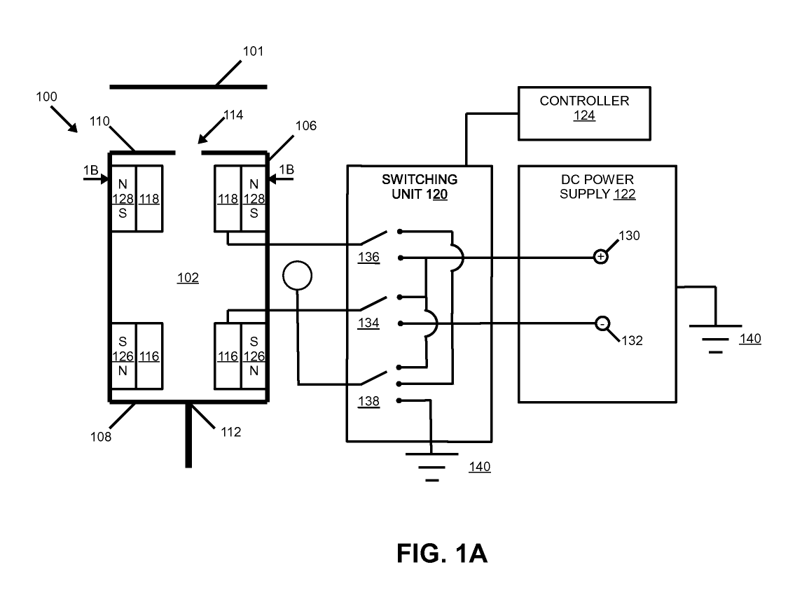

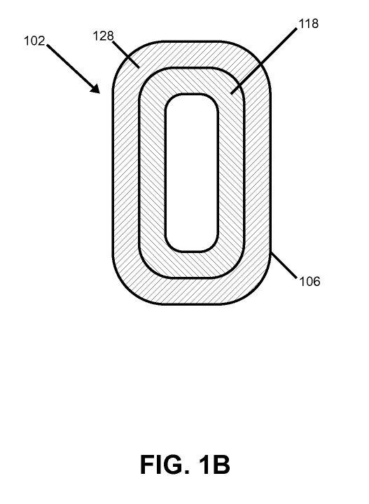

FIG. 1A is a block diagram of an exemplary embodiment of a plasma source 100 in which the ion control techniques described here can be employed. FIG. 1B is a cross section of the plasma source 100 taken along the line 1B-1B. Collectively, FIGS. 1A and 1B are referred to below as “FIG. 1”. The plasma source 100 is suitable for use, for example, in PECVD sputtering systems.

The plasma source 100 comprises a cavity 102 in which ions and electrons are formed. The cavity 102 is formed by or in a housing or other suitable structure. In the particular embodiment shown in FIG. 1, the cavity 102 comprises a racetrack shaped wall 106 and first and second end walls 108 and 110. The racetrack nature of the cavity 102 and the wall 106 are shown in FIG. 1B. In the particular embodiment shown in FIG. 1, the cavity 102 includes one or more inlets 112 located near the first end wall 108 via which process gases are supplied to the cavity 102 and/or a vacuum can be maintained. A discharge aperture 114 is formed in the second end wall 110 through which ions and electrons formed in the cavity 102 are discharged onto a substrate 101.

At least two plasma generating electrodes (targets) 116 and 118 are housed within the cavity 102 of the plasma source 100. In the particular embodiment shown in FIG. 1, the electrodes 116 and 118 have a racetrack shape and are formed along the inside of the wall 106 of the cavity 102. The racetrack shape of the second electrode 118 is shown in FIG. 1B.

The plasma source 100 is coupled to operation electronics which implement the operation of the plasma source 100 described herein. The operation electronics include a switching unit 120, a DC power supply 122, and a controller 124. The two electrodes 116 and 118 are connected to the switching unit 120 that in turn is coupled to the direct current (DC) power supply 122. The controller 124 controls the operation of the switching unit 120 and the DC power supply 122 in order to bias the electrodes 116 and 118 as described in more detail below. The controller 124 can be implemented in any conventional manner (for example, using a suitably programmed micro-controller or other programmable processor).

In the particular embodiment shown in FIG. 1, magnet arrays 126 and 128 are also housed within the cavity 102 in order to control the electron path within the cavity 102. In this example, magnet arrays 126 and 128 have a racetrack shape and are formed along the inside of the wall 106 of the cavity 102. The racetrack shape of the magnet 128 is shown in FIG. 1B. In this example, the poles of the magnet arrays 126 and 128 are arranged in a complimentary fashion with the north pole (N) of the first magnet 126 near the first end wall 108, the south pole (S) of the first magnet 126 near the second magnet 128, the south pole (S) of the second magnet 128 near the first magnet 126, and the north pole (N) of the second magnet 128 near the second wall 110. Magnet arrays 126 and 128 can include permanent magnets or electro-magnetics and are arranged so as to provide a uniform magnetic field.

In the embodiment shown in FIG. 1, the direct current power supply 122 includes a positive output 130 to provide a positive voltage that is used to bias each of the electrodes 116 and 118 as a cathode and that is used to supply a positive ion flux modification bias. The DC power supply 122 also includes a negative output 132 to supply a negative voltage. Each of the electrodes 116 and 118 is coupled to the negative node 132, as described below, in order for the electrode 116 or 118 to be used as an anode. Also, the negative node 132 is used to apply a negative ion flux modification bias to each of the electrodes 116 and 118.

For each pulse, the DC power supply 122 is used to output a positive pulse (for example, 500 Volts) at its positive output 130. For each pulse, the DC power supply 122 is used to output a negative pulse (for example, −350 Volts) at its negative output 132.

The switching unit 120 comprises a first switch 134 that is configured to couple the first electrode 116 to either the positive output 130 or the negative output 132 of the DC power supply 122 under the control of the controller 124. The switching unit 120 further comprises a second switch 136 that is configured to couple the second electrode 118 to either the positive output 130 or the negative output 132 of the DC power supply 122 under the control of the controller 124.

The controller 124 is configured so that, while each pulse is being output by the DC power supply 122, the switches 134 and 136 can be adjusted so that either the positive voltage output or the negative voltage output by the DC power supply 122 is applied to each of the electrodes 116 and 118.

The switching unit 120 (and the switches described herein) and the controller 124 can be implemented using a suitably configured conventional bi-polar pulse power supply controller.

The switching unit 120, direct current power supply 122, and controller 124 (and the general approach of method 200 described below) can be used to control the amount of ion flux that is created using the plasma source 100.

In some implementations of this embodiment, the plasma source 100 can include one or more secondary electrodes 142 disposed outside of the cavity 102. The one or more secondary electrodes 142 can be used to complete the electrical circuit during a flux modification bias. In such embodiments, a third switch 138 in the switching unit 120 can be configured to couple the one or more secondary electrodes 142 to one of the positive output 130 of the DC power supply 122, the negative output 132 of the DC power supply 122, or ground 140 under the control of the controller 124. In some implementations, instead of, or in addition to providing connection to ground 140, the third switch 138 can be set such that the one or more secondary electrodes 142 are floating (e.g., not connected).

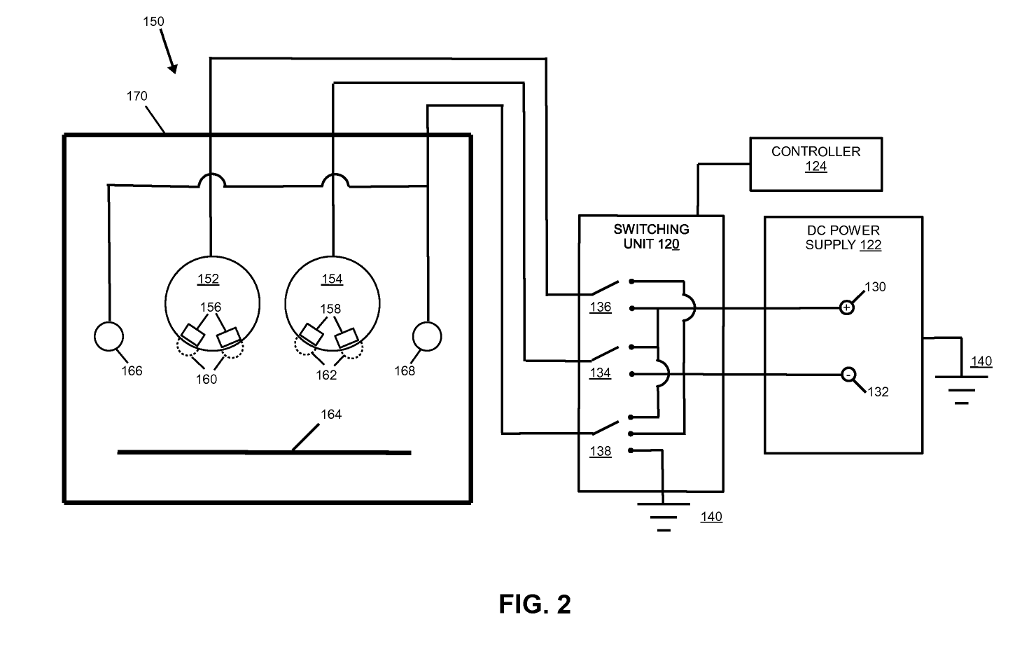

FIG. 2 is a block diagram of an exemplary embodiment of another plasma source, in the form of a sputter magnetron 150, in which the ion control techniques described here can be employed. The sputter magnetron 150 is suitable for use, for example, in PECVD sputtering systems.

The sputter magnetron 150 includes at least two plasma generating electrodes (targets) 152 and 154. In the particular embodiment shown in FIG. 2 the electrodes 152 and 154 are rotary electrodes having a cylindrical geometry and which rotate about a central axis of the respective cylinders. In other examples, the electrodes 152 and 154 can have other shapes and/or can be stationary such as in a planar electrode configuration. FIG. 2 is a cross-sectional view of the cylindrical electrodes 152 and 154.

Magnet arrays 156 and 158 are included within each cylindrical electrode to direct the plasma generation primarily into respective plasma confinement regions 160 and 162 on the surface of the respective electrode 152 and 154. The magnet arrays 156 and 158 are disposed in a location such that the surface of the respective electrode 152 and 154 travels past the respective magnet 156 and 168 as the electrodes 152 and 154 rotate. In an example, the magnet arrays 156 and 158 have a racetrack shape in which the longer dimension of the racetrack shape extends along the axial dimension of the respective electrode 152 and 154. The respective plasma confinement regions 160 and 162 have a shape that corresponds to the shape of the magnet arrays 156 and 158. Accordingly, in this implementation in which the magnet arrays 156 and 158 have a racetrack shape, the electrons that sustain the magnetically confined plasma within the magnetic fields produced by magnet arrays 156 and 158 travel along the surface of the respective electrodes 152 and 154 in a closed-loop racetrack shape. In other examples magnet arrays 156 and 158 can form another shape.

Ions and electrons formed by the electrodes 152 and 154 are directed toward a substrate 164. The two plasma generating electrodes 152 and 154, magnet arrays 156 and 158, and substrate 164 can be housed within a chamber defined by one or more walls 170.

In some implementations of this embodiment, the sputter magnetron 150 can also include one or more secondary electrodes 166 and 168 disposed within the chamber. The one or more secondary electrodes 166 and 168 are electrically isolated from the walls 170 of the chamber and are used to aid in generation of an electric field during ion flux modification pulses as described below. In the embodiment shown in FIG. 2, the secondary electrodes 166 and 168 are disposed outside of (i.e., not in-between) the plasma generating electrodes 152 and 154, and generally in plane with the plasma generating electrodes 152 and 154. In other embodiments, the one or more secondary electrodes 152 and 154 can be disposed at other locations within the cavity. Moreover, although the one or more secondary electrodes 166 and 168 are shown in FIG. 2 as having a cylindrical geometry and as being disposed near the plasma generating electrodes 152 and 154, any suitable geometry or location within the chamber can be used. The one or more secondary electrodes 166 and 168 do not need to be able to generate a plasma.

The sputter magnetron 150 is coupled to operation electronics which implement the operation of the sputter magnetron 150 described herein. The operation electronics include a switching unit 120, a DC power supply 122, and a controller 124. The plasma generating electrodes 152 and 154 and the secondary electrodes 166 and 168 are coupled to a switching unit 120 that in turn is coupled to a DC power supply 122. A controller 124 controls the operation of the switching unit 120 and the DC power supply 122 in order to bias the electrodes 152, 154, 166, and 168 as described in more detail below. The controller 124 can be implemented in any conventional manner (for example, using a suitably programmed micro-controller or other programmable processor).

In the embodiment shown in FIG. 2, the direct current power supply 122 includes a positive output 130 to provide a positive voltage that is used to bias each of the electrodes 152 and 154 as a cathode and that is used to supply a positive ion flux modification bias. The DC power supply 122 also includes a negative output 132 to supply a negative voltage. Each of the electrodes 152 and 154 is coupled to the negative node 132, as described below, in order for the electrodes 152 and 154 to be used as an anode. Also, the negative node 132 is used to apply a negative ion flux modification bias to each of the electrodes 152 and 154.

For each pulse, the DC power supply 122 is used to output a positive pulse (for example, 500 Volts) at its positive output 130. For each pulse, the DC power supply 122 is used to output a negative pulse (for example, −350 Volts) at its negative output 132.

The switching unit 120 comprises a first switch 134 that is configured to couple the first plasma generating electrode 152 to either the positive output 130 or the negative output 132 of the DC power supply 122 under the control of the controller 124. The switching unit 120 also includes a second switch 136 that is configured to couple the second plasma generating electrode 154 to either the positive output 230 or the negative output 132 of the DC power supply 122 under the control of the controller 124. The switching unit 120 also includes a third switch 138 that is configured to couple both of the secondary electrodes 166 and 168 to one of the positive output 130 of the DC power supply 122, the negative output 132 of the DC power supply 122, or ground 140 under the control of the controller 124. In some implementations, instead of, or in addition to providing a connection to ground 140, the third switch 138 can be set such that the secondary electrodes 166 and 168 are floating (e.g., not connected).

The controller 124 is configured so that, while each pulse is being output by the DC power supply 122, the switches 134 and 136 can be adjusted so that either the positive voltage or the negative voltage output by the DC power supply 122 is applied to each of the plasma generating electrodes 152 and 154.

The switching unit 120 (and the switches described herein) and the controller 124 can be implemented using a suitable configured conventional bi-polar pulse power supply controller.

The switching unit 120, DC power supply 122, and the controller 124 (and the general approach of method 200 described below) can be used to control the amount of ion flux that is created using the sputter magnetron 150.

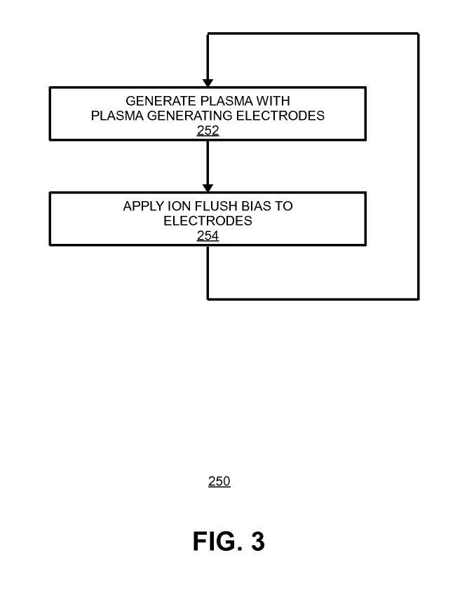

FIG. 3 is a flow diagram of an exemplary embodiment of a method 250 of controlling a plasma source, such as the plasma source 100 of FIG. 1 or the sputter magnetron 150 of FIG. 2. Method 250 can be used to generate a plasma for depositing onto a substrate 101, 164, while controlling the ions at the surface of the substrates 101, 164.

Method 250 includes generating plasma with the plasma generating electrodes (block 252 of FIG. 3). Plasma is generated with the plasma generating electrodes (116, 118, 152, and 154) by biasing one of the plasma generating electrodes (e.g., 116, 152) as a cathode and using the other plasma generating electrode (e.g., 118, 154) as an anode. In some examples, the plasma generating electrodes 116, 118, 152, and 154 can be respectively alternated between cathode and anode during plasma generation as is known to those skilled in the art. For example, a first plasma generating electrode 116, 152 can be biased as a cathode and a second plasma generating electrode 118, 154 can be used as an anode during a first time. The first plasma generating electrode 116, 152 can be biased as a cathode by setting switch 136 to couple the first plasma generating electrode 116, 152 to the positive output 130 of the DC power supply 122. The second plasma generating electrode 118, 154 can be biased as an anode by setting switch 134 to couple second plasma generating electrode 118, 154 to the negative output 132 of the DC power supply 122.

Then, the first plasma generating electrode 116, 152 can be switched to being used as an anode and the second plasma generating electrode 118, 154 can be switched to being biased as a cathode during a second time period. The first plasma generating electrode 116, 152 can be biased as an anode by setting switch 136 to couple the first plasma generating electrode 116, 152 to the negative output 132 of the DC power supply 122. The second plasma generating electrode 118, 154 can be biased as a cathode by setting switch 134 to couple second plasma generating electrode 118, 154 to the positive output 130 of the DC power supply 122.

During a third time period, the first plasma generating electrode 116, 152 can be switched back to being biased as a cathode and the second plasma generating electrode 118, 154 can be switched back to being used as an anode. The plasma generating electrodes 116, 118, 152, and 154 can be alternated between cathode and anode in this manner as many times as desired. Typically, the plasma generating electrodes 116, 118, 152, and 154 are alternated between cathode and anode at rate in the range of 1 kHz to 100 kHz, however, other frequencies can also be used. In some examples of block 252, plasma is generated without alternating the plasma generating electrodes 116, 118, 152, and 154 between cathode and anode; instead the plasma generating electrodes 116, 118, 152, and 154 are maintained as either cathode or anode respectively. Plasma can be generated at block 252 for any desired length of time.

After generating plasma, one or more ion flux modification biases can be applied to the plasma generating electrodes 116, 118, 152, and 154. An ion flux modification bias includes biasing both plasma generating electrodes 116, 118, 152, and 154 of a plasma source 100, 150 as a cathode, or biasing both plasma generating electrodes 116, 118, 152, and 154 as an anode. An ion flux modification bias can be used to control the ions in the plasma that is generated. In particular, an ion flux modification bias can be used to control the number of species (flux) that will come into contact with the substrate 101, 164. To adjust the number of species that will come into contact with the substrate 101, 164, the current and/or length of the flux modification bias applied to the plasma generating electrodes 116, 118, 152, and 154 can be adjusted. An ion flux modification bias can also be used to control the net energy (velocity) of the species (flux) that will come into contact with the substrate 101, 164. To adjust the net energy of the species, the voltage of the flux modification pulse bias applied to the plasma generating electrodes 116, 118, 152, and 154 can be adjusted.

A positive ion flux modification bias is implemented by coupling both plasma generating electrodes 116, 152 and 118, 154 of a plasma source 100, 150 to the positive output 130 of the DC power supply 122 at the same time. Both plasma generating electrodes 116, 152 and 118, 154 can be coupled to the positive output 130 of the DC power supply 122 by setting both switches 136 and 134 to couple the respective plasma generating electrodes 116, 152, 118, 154 to the positive output 130. A negative ion flux modification bias is implemented by coupling both plasma generating electrodes 116, 118, 152, and 154 of a plasma source 100, 150 to the negative output 132 of the DC power supply 122 at the same time. Both plasma generating electrodes 116, 152 and 118, 154 can be coupled to the negative output 132 of the DC power supply 122 by setting both switches 136 and 134 to couple the respective plasma generating electrodes 116, 152, 118, 154 to the negative output 132. To implement an ion flux modification bias, the plasma generating electrodes 116, 118, 152, 154 are held in either the positive or negative bias for a length of time sufficient to modify the direction and/or velocity of the ions.

The one or more secondary electrodes 142 can be biased to the opposite polarity as the plasma generating electrodes 116 and 118 during an ion flux modification bias, to aid in generating an electric field around the plasma generating electrodes 116 and 118 for the ion flux modification pulse. For example, while a positive ion flux modification bias is applied to the plasma generating electrodes 116, 118, 152, 154, switch 138 can be set to couple the negative output 132 of the DC power supply 122 to the one or more secondary electrodes 142, 166, 168. During a negative ion flux modification bias, the one or more secondary electrodes 142, 166, 168 can be coupled to the positive output 130 of the DC power supply 122. The one or more secondary electrodes 142, 166, 168 can be coupled to ground 140 or floating when a flux modification bias is not being applied (e.g., during plasma generation) to the plasma generating electrodes 116, 118, 152, 154.

In embodiments that do not include any secondary electrodes, the walls 106, 108, and 110 of the cavity 102 of plasma source 100 or walls 170 of the chamber of the sputter magnetron 150 can function as a secondary electrode(s) and be biased to the opposite polarity of the plasma generating electrodes 116, 118, 152, 154 during a flux modification bias. In such embodiments, the walls 106, 108, 110, 170 can be coupled to the third switch 138. The walls 106, 108, 110, 170 can be coupled to ground 140 or floating when a flux modification bias is not being applied (e.g., during plasma generation) to the plasma generating electrodes 116, 118, 152, 154.

A positive ion flux modification bias is used to increase the number of species and/or net energy at the surface of the substrate 101, 164. The positive ion flux modification bias can drive the ions away from the plasma generating electrodes 116, 118, 152, 154, toward the substrate 101, 164. A negative ion flux modification bias is used to decrease the number of species and/or net energy at the surface of the substrate 101, 164. The negative ion flux modification bias can draw the ions towards the plasma generating electrodes 116, 118, 152, and 154, away from the substrate 101, 164. In some examples, a single ion flux modification bias (i.e., either positive or negative) can be applied at block 254. In other examples, multiple ion flux modification biases can be applied at block 254. For example, a negative ion flux modification bias may be used to draw the ions together and toward the plasma generating electrodes, followed by a positive ion flux modification bias which pushes the ions toward the substrate 101, 164. Other schemes are also possible.

The magnitudes of the biases applied during generation of plasma and during ion flux modification bias(es), as well as the duration of bias, can be varied to suit the particular application. For example, in one implementation of such an embodiment, the anode and cathode biases that are applied to the plasma generating electrodes 116, 118, 152, and 154 during plasma generating are 150 Volts and −350 Volts, respectively, the positive ion flux modification bias applied to the electrodes 116, 118, 152, and 154 is 600 Volts. It is to be understood, however, that these parameters will be varied based on the particular application.

The ability to vary the magnitude and duration of the ion flux modification pulses, in addition to varying the magnitudes and durations of plasma generation, provides an additional degree of control that can be used to more precisely control the plasma source 100, 150. Also, by applying the ion flux modification biases to the electrodes 116, 118, 152, and 154 in addition to alternating between cathode and anode biasing, ions may be discharged from the plasma source 100, 150 at a sufficient energy level for some high-energy applications.

After the one or more flux modification biases are implemented, method 250 can end or can return to generating plasma with the plasma generating electrodes (block 252 of FIG. 2). In examples where method 250 repeats blocks 252 and 154, the method 250 continues in this manner, alternating between generating plasma and implementing ion flux modification biases, as many times as desired for the particular application. Subsequent (e.g., the second time and on) performances of block 252 and 254 can be the same or different than previous performances during the method 250. For example, the total length of time spent generating plasma and/or the number of times or frequency of alternating between anode and cathode, voltages used, and/or other parameters can be the same or different for subsequent performances of block 252. Similarly, the total length of time, number of ion flux modification biases, or other parameters can be the same or different for subsequent performances of block 254.

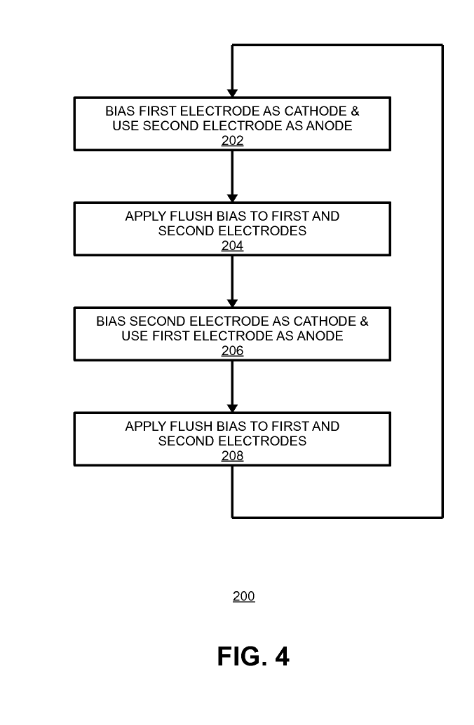

FIG. 4 is a flow diagram of method 200 which is an implementation of method 250. The implementation of method 200 shown in FIG. 4 is described here as being implemented using the plasma source 100 shown in FIG. 1, though it is to be understood that it can also be used with the sputter magnetron 150 and with other plasma sources. Method 200 can be used to control the ion flux toward the substrate 101 that is created using the plasma source 100.

Method 200 is performed once for each complete cycle (also referred to here as a “pulse cycle”.

Method 200 comprises, during a first pulse in each pulse cycle, biasing the first electrode 116 as a cathode and using the second electrode 118 as an anode (block 202 of FIG. 2), and, during a second pulse in each pulse cycle, applying an ion flux modification bias to the two electrodes 116 and 118 (block 204 of FIG. 2).

Method 200 further comprises, during a third pulse in each pulse cycle, biasing the second electrode 118 as a cathode and using the first electrode 116 as an anode (block 206 of FIG. 2), and, during a fourth pulse in each pulse cycle, applying an ion flux modification bias to the two electrodes 116 and 118 (block 208 of FIG. 2).

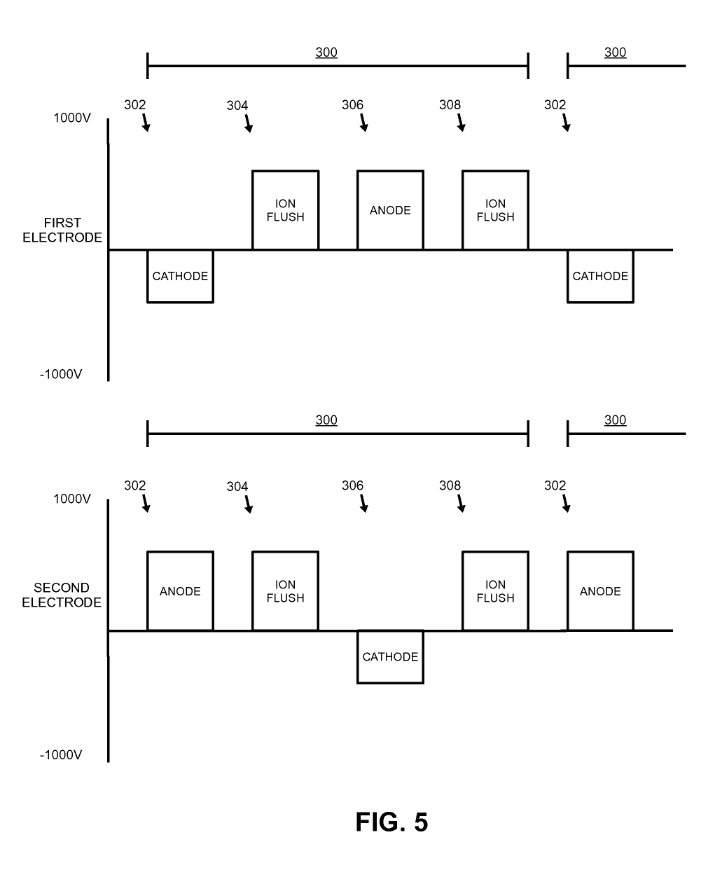

The plasma source 100 and method 200 can be used to increase the ion flux toward the substrate 101 that is created using the plasma source 100 by using the positive voltage output by the DC power supply 122 as a positive ion flux modification bias during the second and fourth pulses of each pulse cycle. This is illustrated in FIG. 5.

During the first pulse 302 of each pulse cycle 300, the first electrode 116 is biased as a cathode by using the first switch 134 to couple the first electrode 116 to the negative output 132 of the DC power supply 122 and the second electrode 118 is used as an anode by using the second switch 136 to couple the second electrode 118 to the positive output 130 of the DC power supply 122.

During the second pulse 304 of each pulse cycle 300, a positive ion flux modification bias is applied to the two electrodes 116 and 118 of the plasma source 100 by using the first and second switches 134 and 136 to couple the electrodes 116 and 118 to the positive output 130 of the DC power supply 122.

During the third pulse 306 in each pulse cycle 300, the second electrode 118 is biased as a cathode by using the second switch 136 to couple the second electrode 118 to the negative output 132 of the DC power supply 122 and the first electrode 116 is used an anode by using the first switch 134 to couple the first electrode 116 to the positive output 130 of the DC power supply 122.

During the fourth pulse 308 in each pulse cycle 300, a positive ion flux modification bias is applied to the two electrodes 116 and 118 of the plasma source 100 by using the first and second switches 134 and 136 to couple the electrodes 116 and 118 to the positive output 130 of the DC power supply 122.

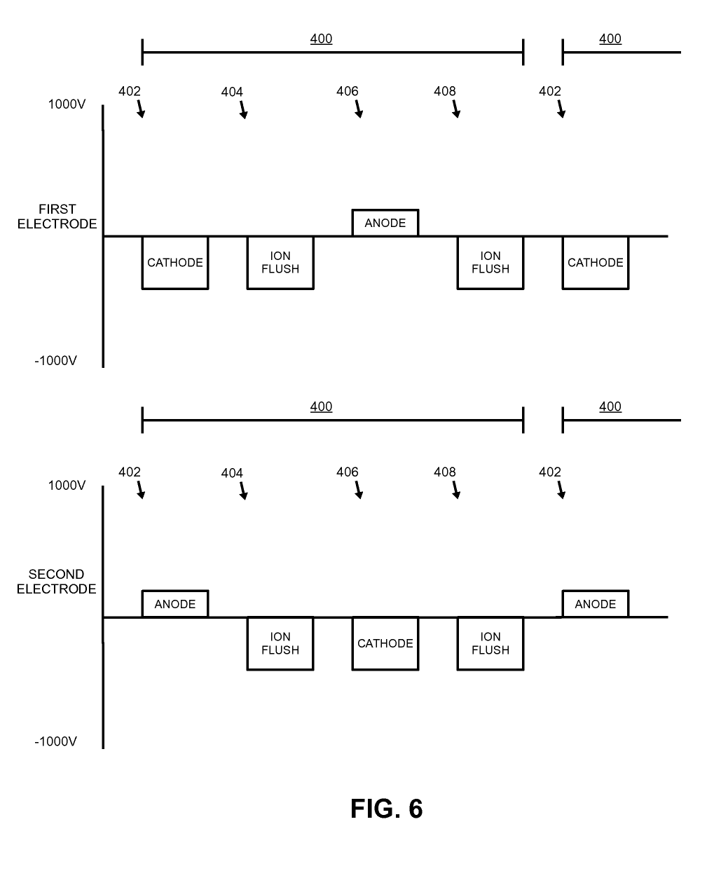

The plasma source 100 and method 200 can also be used to decrease the ion flux toward the substrate 101 that is created using the plasma source 100 by using the negative voltage output by the DC power supply 122 as a negative ion flux modification bias during the second and fourth pulses of each pulse cycle. This is illustrated in FIG. 6.

During the first pulse 402 of each pulse cycle 400, the first electrode 116 is biased as a cathode by using the first switch 134 to couple the first electrode 116 to the negative output 132 of the DC power supply 122 and the second electrode 118 is used as an anode by using the second switch 136 to couple the second electrode 118 to the positive output 130 of the DC power supply 122.

During the second pulse 404 of each pulse cycle 400, a negative ion flux modification bias is applied to the two electrodes 116 and 118 of the plasma source 100 by using the first and second switches 134 and 136 to couple the electrodes 116 and 118 to the negative output 132 of the DC power supply 122.

During the third pulse 406 in each pulse cycle 400, the second electrode 118 is biased as a cathode by using the second switch 136 to couple the second electrode 118 to the negative output 132 of the DC power supply 122 and the first electrode 116 is used an anode by using the first switch 134 to couple the first electrode 116 to the positive output 130 of the DC power supply 122.

During the fourth pulse 408 in each pulse cycle 400, a negative ion flux modification bias is applied to the two electrodes 116 and 118 of the plasma source 100 by using the first and second switches 134 and 136 to couple the electrodes 116 and 118 to the negative output 132 of the DC power supply 122.

In this way, the ion control techniques described here can be used to both increase and to decrease the ion flux toward the substrate 101 that is created using the plasma source 100 by using either a positive flux modification bias or a negative flux modification bias, respectively.

The magnitudes of the biases applied during each of the four pulses in each pulse cycle, as well as the duration of each pulse, can be varied to suit the particular application. For example, in one implementation of such an embodiment, the anode and cathode biases that are applied to the electrodes 116 and 118 during the first and third pulses are 150 Volts and −350 Volts, respectively, the positive ion flux modification bias applied to the electrodes 116 and 118 is 600 Volts, with the duration of the first pulse being 5 microseconds, the duration of the second pulse being 2 microseconds, the duration of the third pulse being 5 microseconds, the duration of the fourth pulse being 2 microseconds, and the duration of the overall pulse cycle being 14 microseconds. It is to be understood, however, that these parameters will be varied based on the particular application.

The ability to vary the magnitude and duration of the ion flux modification pulses (the second and fourth pulses in each pulse cycle), in addition to varying the magnitudes and durations of the pulses in which the electrodes 116 and 118 are alternated between cathode and anode (the first and second pulses in each pulse cycle), provides an additional degree of control that can be used to more precisely control the plasma source 100. Also, by applying the ion flux modification biases to the first and second electrodes 116 and 118, in addition to alternating between cathode and anode biasing, ions may be discharged from the plasma source 100 at a sufficient energy level for some high-energy applications.

Although the exemplary embodiment of a plasma source 100 described above in connection with FIGS. 1-4 has a racetrack-shaped cavity 102 and wall 106, it is to be understood that the ion control techniques described here can be used with other types of plasma sources, such as plasma sources that are shaped differently (for example, plasma sources having a cylindrical-shaped cavity).

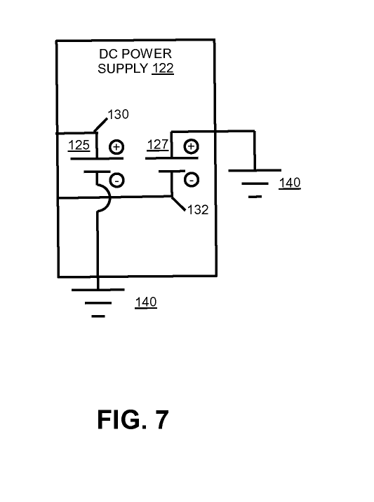

FIG. 7 is a block diagram of an example DC power supply 122 that can be used in the system of FIGS. 1 and 2. The example DC power supply 122 includes two DC power supplies 125 and 127. A first DC power supply 125 is used to supply the positive voltage for node 130 which is used to bias each of the electrodes 152, 154, 166, and 168 as a cathode and that is used to supply a positive ion flux modification bias. A second DC power supply 127 is used to supply a negative voltage for node 132. Each of the electrodes 152, 154, 166, and 168 is coupled to the second DC power supply 127 for the electrodes 152, 154, 166, and 168 to be used as an anode. Also, the second DC power supply 127 is used to apply a negative ion flux modification bias.

The first DC power supply 125 is used to output a positive pulse (for example, 500 Volts) at its positive output 130. The negative terminal of the first DC power supply 125 is coupled to ground 140. The second DC power supply 127 is used to output a negative pulse (for example, −350 Volts) at its negative output 132. The positive terminal of the second DC power supply 127 is coupled to ground 140.

Although the DC power supply 122 is described above as being implemented using two DC power supplies 125 and 127 it is to be understood that other numbers of power supplies can be used (for example, one or more than two).

Although the ion control techniques are described above in connection with a single plasma source, it is to be understood that these ion control techniques can be used with multiple plasma sources that are controlled as a single unit (for example, where a different plasma source is used to bias the electrodes during each pulse of each pulse cycle).

A number of embodiments have been described. Nevertheless, it will be understood that various modifications to the described embodiments may be made without departing from the spirit and scope of the claimed invention. Also, combinations of the individual features of the above-described embodiments are considered within the scope of the inventions disclosed here.

1. An apparatus comprising:
a plasma source including at least two electrodes configured to generate plasma;
electronics coupled to the plasma source, the electronics configured to:
generate plasma with the at least two electrodes; and
apply an ion flux modification bias to the at least two electrodes.

2. The apparatus of claim 1, wherein apply an ion flux modification bias includes apply a positive voltage to the at least two electrodes concurrently.

3. The apparatus of claim 1, wherein apply an ion flux modification bias includes apply a negative voltage to the at least two electrodes concurrently.

4. The apparatus of claim 1, wherein generate plasma includes alternate a first of the at least two electrodes between being biased as a cathode and being biased as an anode, and alternate a second of the at least two electrodes between being biased as an anode and being biased as a cathode, wherein the second electrode is biased as an anode while the first electrode is biased as a cathode and the second electrode is biased as a cathode while the first electrode is biased as an anode.

5. The apparatus of claim 1, wherein the electronics are configured to apply one or more ion flux modification biases after generating plasma, and to repeat generating plasma and applying one or more ion flux modification biases one or more times.

6. The apparatus of claim 1, wherein the electronics include a switching unit coupled to the at least two electrodes, and one or more direct current power supplies coupled to the switching unit.

7. The apparatus of claim 1, comprising:
one or more secondary electrodes coupled to the electronics, wherein the electronics are configured to bias the one or more secondary electrodes with a negative voltage during a positive ion flux modification bias and to bias the one or more secondary electrodes with a positive voltage during a negative ion flux modification bias.

8. The apparatus of claim 1, wherein the at least two electrodes are part of a plasma source that is configured to output plasma from a discharge aperture of a cavity or are part of a sputter magnetron.

9. A method of controlling a plasma source having at least two electrodes configured to generate plasma, the method comprising:
generating plasma with the at least two electrodes; and
applying an ion flux modification bias to the at least two electrodes.

10. The method of claim 9, wherein applying an ion flux modification bias includes applying a positive voltage to the at least two electrodes concurrently.

11. The method of claim 9, wherein applying an ion flux modification bias includes applying a negative voltage to the at least two electrodes concurrently.

12. The method of claim 9, wherein generating plasma includes:
alternating a first of the at least two electrodes between being biased as a cathode and being biased as an anode, and alternating a second of the at least two electrodes between being biased as an anode and being biased as a cathode, wherein the second electrode is biased as an anode while the first electrode is biased as a cathode and the second electrode is biased as a cathode while the first electrode is biased as an anode.

13. The method of claim 9, comprising:
applying one or more ion flux modification biases after generating plasma; and
repeating the acts of generating plasma and applying one or more ion flux modification biases one or more times.

14. The method of claim 9, comprising:
biasing one or more secondary electrodes with a negative voltage during a positive ion flux modification bias and biasing the one or more secondary electrodes with a positive voltage during a negative ion flux modification bias.

15. An electrical circuit for a plasma source, the electrical circuit comprising:
a switching unit configured to couple to at least two electrodes of the plasma source, the at least two electrodes configured to generate plasma; and
a controller coupled to the switching unit, wherein the controller is configured to control the switching unit to:
generate plasma with the at least two electrodes; and
apply an ion flux modification bias to the at least two electrodes.

16. The electrical circuit of claim 15, wherein apply an ion flux modification bias includes apply a positive voltage to the at least two electrodes concurrently.

17. The electrical circuit of claim 15, wherein apply an ion flux modification bias includes apply a negative voltage to the at least two electrodes concurrently.

18. The electrical circuit of claim 15, wherein generate plasma includes alternate a first of the at least two electrodes between being bias as a cathode and being biased as an anode, and alternate a second of the at least two electrodes between being biased as an anode and being biased as a cathode, wherein the second electrode is biased as an anode while the first electrode is biased as an cathode and the second electrode is biased as a cathode while the first electrode is biased as an anode.

19. The electrical circuit of claim 15, wherein the controller is configured to apply one or more ion flux modification biases after generating plasma, and to repeat generating plasma and applying one or more ion flux modification biases one or more times.

20. The electrical circuit of claim 15, wherein the controller is configured to bias one or more secondary electrodes of the plasma source with a negative voltage during a positive ion flux modification bias and to bias the one or more secondary electrodes with a positive voltage during a negative ion flux modification bias.
